(19) United States
(12) Patent Application Publication
(10) Pub. No.: US 2010/0140796 A1
(43) Pub. Date: Jun. 10, 2010

(54) Manufacturing method of semiconductor device, and semiconductor device

(75) Inventors: Kiminori Ishido, Kanagawa (JP); Teruji Inomata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/591,364

(22) Filed: Nov. 17, 2009

(30) Foreign Application Priority Data
Nov. 18, 2008 (JP) 2008-294635

(51) Int. Cl. H01L 23/498; H01L 21/60

(52) U.S. Cl. 257/737; 438/613; 257/E21.508; 257/E23.068

(57) ABSTRACT

A manufacturing method of a semiconductor device includes a first to fourth steps. The first step includes a step of determining an UBM (Under Bump Metal) radius of an UBM of a chip. The second step includes a step of determining a first curvature radius of a solder bump formed on the UBM. The third step includes a step of determining a SRO (Solider Resist Opening) radius of a SRO of a substrate such that a ratio of the SRO radius to the UMB radius is in a range from 0.8 to 1.2. The fourth step includes a step of determining a second curvature radius of a spare solder formed on an electrode in the SRO such that the second curvature radius is equal to or more than the first curvature radius.

### INCORPORATION BY REFERENCE

This application is based upon and claims the benefit of priority from Japanese patent application No. 2008-294635 filed on Nov. 18, 2008, the disclosure of which is incorporated herein in its entirety by reference.

### BACKGROUND OF THE INVENTION

1. Field of the Invention

The present invention relates to a manufacturing method of a semiconductor device and the semiconductor device. Particularly, the present invention relates to a manufacturing method of a flip-chip type semiconductor device and the flip-chip type semiconductor device.

2. Description of Related Art

According to a typical flip-chip type semiconductor device, a chip is connected to a substrate by using a following method. That is, first, a material is selected, of which melting point is lower than that of a solder bump (a solder ball or the like) located on a chip side, for a spare solder located on a substrate side. Then, when a connection process is carried out between the chip and the substrate, only the spare solder on the substrate side is melted and diffused into the solder bump on the chip side. Therefore, the shape of the spare solder on the substrate side is designed independently from a curvature radius of the solder bump on the chip side when the solider bump is melted.

In many cases, in order to produce a difference between the melting point of the solder on the chip and the melting point of the solder on the substrate for connecting the chip to the substrate, the following materials are used for the solders in many cases. That is, the solder, which contains high levels of lead having a melting point higher than 300° C., is used for the chip. The eutectic solder, of which melting point is 187° C., is used for the substrate. However, this is not favorable in consideration of an environmental measure such as a Restriction of the Use of Certain Hazardous Substances in Electrical and Electronic Equipment (RoHS: Restriction of Hazardous Substances) or the like since any of the solder on the chip side and the solder on the substrate side includes lead.

However, in the case of selecting a lead-free solder as a member using no lead on a connection portion between the chip and the substrate in realization of solder lead-free as an environmental measure and making the materials of the solder bump on the chip side and the spare solder on the substrate side the same, a design requirement is not clear.

For example, typically, the spare solder having the melting point lower than that of the solder bump is used, and when the connection process is carried out between the solder bump and the spare solder, the spare solder is only heat-melted to connect the solder bump to the spare solder, so that there has been no change in the shape of the solder bump during the connection process. However, when the solder bump and the spare solder are made of the same materials, the melting points thereof are also the same. Therefore, when the spare solder is heat-melted, the solder bump is also melted, and this changes the shape of the solder bump during the connection process between the solder bump and the spare solder.

In addition, in the case of selecting the materials having the same melting points for the spare solder on the substrate side and the solder bump on the chip side, and heat-bonding the spare solder and the spare solder together by melting both of them, a solder suction phenomenon (suction) occurs depending on a size of the solder bump and an interval between the semiconductor chip and the package substrate. That is, the spare solder whose solder amount is less than that of in the solder bump is sucked by the solder bump side. This may generate an electric connection defect. If the connection defect is generated, this semiconductor device will be discarded as defective goods. In order to reduce a yield loss due to the defective goods, a design to prevent the connection defect is required.

As related techniques, a wiring substrate with semiconductor components is disclosed in Japanese Laid-Open Patent Application JP-P 2007-141973 A (patent document 1) and Japanese Laid-Open Patent Application JP-P 2006-156996 A (patent document 2). In these related techniques, the semiconductor component is flip-chip connected to a substrate side pad array via an individual solder connection part at a component side pad array. In solder resist layers on the semiconductor component side and the substrate side, respectively, D0/D is adjusted to be 0.70 or more and 0.99 or less, where an inner diameter at a bottom surface of a substrate side opening part is defined as D and an internal diameter at a bottom surface of a component side opening part is defined as D0.

In addition, Japanese Laid-Open Patent Application JP-P 2005-72212 A (patent document 3) discloses an electronic component, a manufacturing method of the same, and an electronic apparatus. According to this related technique, in the electronic component, a first substrate and a second substrate are located being opposed, and solder bumps are arranged individually between a plurality of conductive parts provided to the first substrate and a plurality of conductive parts provided to the second substrate. This electronic component is provided with at least a solder bump, of which a side surface is convexed outward and of which curvature radius of a curved surface made by the side surface is larger than the curvature radius of a circle whose diameter corresponds to an interval between the first substrate and the second substrate.

The patent documents 1 and 2, by optimizing a relation between a diameter of a Solder Resist Opening (SRO) and a diameter of an Under Bump Metal (UBM), intend to prevent cracks and defects at a solder connection part due to a heat stress upon assembly while preventing short-circuit between the solders. In the patent document 3, compared to a typical solder bump, the solder bump constructing the electronic component has a lower rigidity at a center part in a height direction of the bump. Therefore, in the case where this solder bump is affected by an extra force and a heat, a concentration of stress to a vicinity of the bonding part bonding with the conductive part that corresponds to a base of the solder bump is prevented.

However, in any of the above-mentioned cases, a movement of a solder in melting process, such as a solder suction phenomenon, is not considered.

Generally, in a reflow step, when a solder bump and a spare solder are heat-melted and connected together, the spare bump is sucked by a solder bump side and this may generate an electric connection defect of a solder.

### SUMMARY OF THE INVENTION

The present invention seeks to solve one or more of the above problems, or to improve upon those problems at least in part

In one embodiment, a manufacturing method of a semiconductor device includes: determining an UBM (Under Bump Metal) radius of an UBM of a chip; determining a first curvature radius of a solder bump formed on the UBM; determining a SRO (Solider Resist Opening) radius of a SRO of a substrate such that a ratio of the SRO radius to the UMB radius is in a range from 0.8 to 1.2; and determining a second curvature radius of a spare solder formed on an electrode in the SRO such that the second curvature radius is equal to or more than the first curvature radius.

In another embodiment, a semiconductor device includes: a solder resist configured to be provided with a SRO (Solider Resist Opening) of a substrate, a ratio of a SRO radius of the SRO to an UBM (Under Bump Metal) radius of an UBM of a chip mounted on the substrate being in a range from 0.8 to 1.2; and a spare solder configured to be arranged on an electrode in the SRO, and have a curvature radius is equal to or larger than a curvature radius of a solder bump formed on the UBM.

A manufacturing method of a semiconductor device and a semiconductor device according to the present invention make it possible to prevent an electric connection defect due to a solder suction phenomenon (suction). For example, in the case where a solder bump on a semiconductor chip side and a spare solder on a package substrate side are made of same materials and a semiconductor chip is connected to a package substrate by heat-melting the solder bump and the spare solder at the same time, an electric connection defect caused by sucking the spare solder to the solder bump side can be avoided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a model view showing a configuration example of a semiconductor device according to the present invention;

FIG. 2 is a diagram showing an experimental result for explaining a lower limit value of a SRO/UBM ratio;

FIG. 3 is a diagram for explaining a relation between a SRO radius and a height h2 of a spare solder;

FIG. 4 is a diagram showing a stress that is applied along a surface of a solder;

FIG. 5 is a model view showing a configuration example after connection between a semiconductor chip and a package substrate; and

FIG. 6 is a flow chart showing a procedure of determining design values for solder connection.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, an embodiment of the present invention will be described referring to the attached drawings.

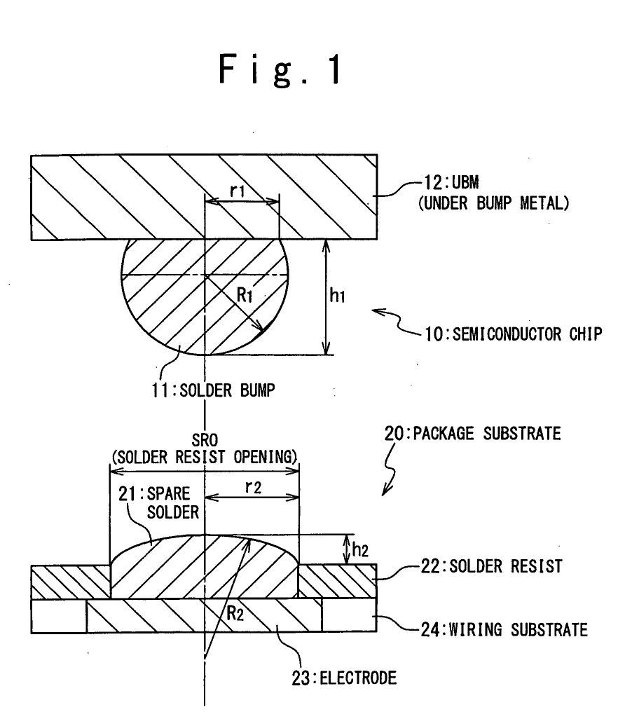

FIG. 1 shows a configuration example of a semiconductor device according to the embodiment of the present invention.

The semiconductor device according to the embodiment includes a semiconductor chip 10 and a package substrate 20.

In this case, it is assumed that the semiconductor device according to the embodiment is a flip-flop type semiconductor device in which the semiconductor chip 10 and the package substrate 20 are connected via solder bumps. As an example of the semiconductor chip 10, a silicon chip (a bare chip) is supposed. As an example of the package substrate 20, a wiring substrate (wiring circuit board) or a resin substrate, on which the semiconductor chip 10 is mounted, is supposed. The package substrate 20 may be a printed circuit board (printed substrate). However, the semiconductor chip 10 and the package substrate 20 are not limited to these examples in the present invention.

The semiconductor chip 10 includes a solder bump 11 and an Under Bump Metal (UBM) 12. The solder bump 11 is formed on the UBM 12 arranged on the semiconductor chip 10.

The package substrate 20 includes a spare solder 21, a solder resist 22, an electrode 23, and a wiring substrate 24, respectively.

On the package substrate 20, the spare solder 21 is formed at a site being opposed to the semiconductor bump 11. In addition, on the package substrate 20, the solder resist 22 has an opening at a position being opposed to the semiconductor bump 11 of the semiconductor chip 10. The solder resist 22 is made of an insulating layer. In other words, the solder resist opening indicates an opening in an insulating layer. On the electrode 23 arranged in this solder resist opening, the spare solder 21 is arranged. The electrode 23 is a substrate pad, which is embedded in the wiring substrate 24.

According to the semiconductor device of the embodiment, the semiconductor bump 11 and the spare solder 21 are brought into contact with each other and heat-melted.

In the semiconductor device of the embodiment, a material of the spare solder 21 arranged on the electrode 23 arranged in the solder resist opening is the same as a material of the solder bump 11 formed on an UBM arranged on the semiconductor chip 10.

Generally, when the solder bump 11 and the spare solder 21 are made of same materials, there is a possibility that a solder suction phenomenon (suction) occurs during a heat-melting process. According to the semiconductor device of the embodiment, in order to avoid an electric connection defect caused when the spare solder 21 is sucked on a side of the solder bump 11, a ratio of a radius r2 (a SRO radius) of the solder resist opening and an UBM radius r1, namely, a ratio r2/r1 is defined to be 0.8 or more and 1.2 or less. In other words, the ratio r2/r1 is defined as “0.8≦(r2/r1)≦1.2”. Further, the UBM radius indicates a radius of a contact portion (a bonded surface) between the solder bump 11 and the UBM 12.

A reason why the ratio r2/r1 is defined to be 0.8 or more and 1.2 or less will be described below.

### <A Lower Limit Value “0.8” of SRO/UBM Ratio>

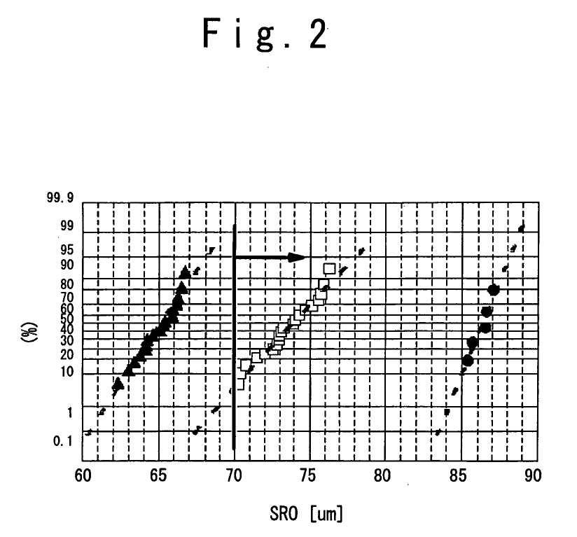

FIG. 2 is a diagram showing an experimental result for explaining a reason why a lower limit value of a SRO/UBM ratio is defined as 0.8.

Referring to FIG. 2, a solid triangle (▴) denotes data indicating a distribution of respective SRO measured values of a lot, in which an average value of the finished SRO measured values is 66 μm, where an UBM=85 μm. In other words, the solid triangle (▴) denotes the data showing a dispersion of the SRO measured values in the lot at the average value of 66 μm.

An open box (□) denotes data indicating a distribution of respective SRO measured values of a lot, in which an average value of the finished SRO measured values is 74 μm, where the UBM=85 μm. In other words, the open box (□) denotes the data showing a dispersion of the SRO measured values in the lot at an average value of 74 μm.

A solid circle () denotes data indicating a distribution of respective SRO measured values of a lot, in which an average value of the finished SRO measured values is 86 μm, where the UBM=85 μm. In other words, the solid circle () denotes the data showing a dispersion of the SRO measured values in the lot at an average value of 86 μm.

In these cases, in the lot denoted by the solid triangles (▴), open faults occur in all SROs. However, in the lots denoted by the open boxes (□) and the solid circles (), no open fault occurs. In other words, an area of the SROs where the faults occur is at least a range that is denoted by the solid triangles (▴). However, an area of the SROs where no open fault occurs is at least a range that is denoted by the open boxes (□) and the solid circles().

As a result, when the SRO is 70 μm or more, it is ensured that no fault occurs, and when the SRO is 67 μm or less, the faults occur. In other words, it is ensured that no fault occurs in the case of the ration r2/r1 is 70/85=0.82, and the faults occur in the case of the ration r2/r1 is 67/85=0.79. Therefore, the ratio r2/r1≧0.8 is defined.

In addition, in the case of using a substrate having an average value 74 μm of the finished SRO, where UBM=85 μm, the suction does not occur. In this case, the ratio is 74/85=0.87. Further, in the case of using a substrate having an average value 66 μm of the finished SRO, where UBM=85 μm, the suction does not occur in most of the connection places. In this case, the ratio is 66/85=0.76. Accordingly, if the SRO/UBM ratio is 0.8, it is perceived that occurrence of the suction can be avoided.

Further, it is perceived that the dispersion of the SRO is not enough as a condition for occurrence of the suction, and it is considered that occurrence of the suction is affected by a relation between “an average value and dispersion in a volume of the spare solder” and “an average value and dispersion in a volume of the solder bump”.

### <An Upper Limit Value “1.2” of SRO/UBM Ratio>

The fault due to opposite suction, in which the solder bump is sucked by the spare bump side, corresponds to the case that the ratio between the UBM radius and the SRO radius is inverted compared to the case of the above-mentioned suction. Therefore, the SRO/UBM ratio needs to be 1/0.8=1.25 or less for avoiding the opposite suction. In practice, it is considered that the SRO/UBM ratio needs to be lower than 1.25 since the opposite suction is made large due to a relation between a curvature radius R1 of the solder bump 11 and a curvature radius R2 of the spare solder 21. Therefore, 1.20 is preferable as the SRO/UBM ratio.

Further, in the experiment, it was confirmed that there is no problem even when the actual measurement value of the SRO is 100 μm. In this case, the ration r2/r1 is 100/85=1.18. Accordingly, it is perceived that the opposite suction does not occur when the ration r2/r1 is in a range of up to about 1.20.

When the above-described conditions are satisfied, a height h1 of the solder bump 11 on a side of the semiconductor chip 10 is higher than a height h2 of the spare solder 21 on a side of the package substrate 20. In other words, “h1>h2” is established. In addition, correctly representing the height h2 of the spare solder 21, the height h2 of the spare solder 21 corresponds to a height of a portion that is protruded from the SRO in the spare solder 21 (namely, a height from the surface of the solder resist 22).

In addition, according to the semiconductor of the embodiment, a solder amount of the solder bump 11 and a solder amount of the spare solder 21 are defined so that the curvature radius R1 of the solder bump 11 and the curvature radius R2 of the spare solder 21 satisfy a relation of “R2≧R1” In this case, to simultaneously satisfy “h1>h2” and “R2≧R1” defines that the solder amount of the solder bump 11 on the side of the semiconductor chip 10 is larger than the solder amount of the spare solder 21 on the side of the package substrate 20. As a reason of this, other than the fact that a solder ball is used for the solder bump 11, it is considered that the solder resist 22 is mounted on the side of the package substrate 20 and this makes it difficult to increase the solder amount of the spare solder 21 on the side of the package substrate 20.

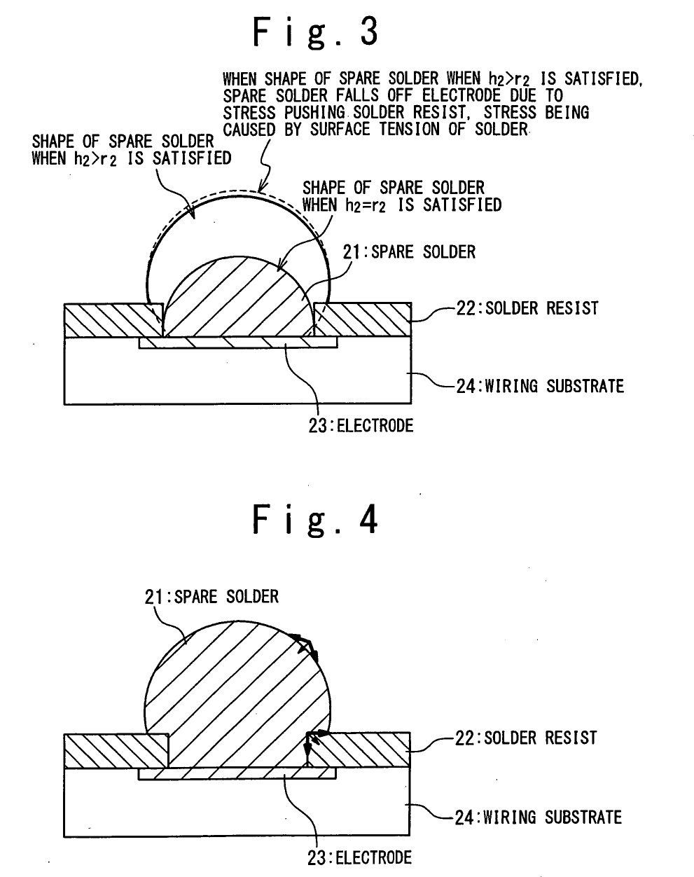

In addition, in the semiconductor device according to the embodiment, the radius r2 of the solder resist opening (the SRO radius) is defined to be the height h2 of the spare solder 21 or more. In other words, “r2≧h2” is given. The reason for this is explained with reference to FIG. 3. FIG. 3 is a diagram for explaining the reason why the SRO radius (r2) is equal to or more than the height h2 of the spare solder. Assuming that “h2>r2” is established, if the shape of the package substrate 20 is as shown in FIG. 3, since a surface tension produced when the spare solder 21 is melted interferes with the solder resist 22, the spare solder 21 may fall off the package substrate 20.

For example, FIG. 4 is a diagram showing a stress that is applied along a surface of a solder. At the place where the spare solder 21 interferes with the solder resist 22, as shown in FIG. 4, since the spare solder 21 is affected by an obliquely upper stress due to a counteraction of the surface tension, this makes it easier for the spare solder 21 to fall off the electrode 23. If solder wettability between the solder resist 22 and the spare solder 21 is not good, since the solder surfaces are generally pulled each other due to the surface tension, as shown in FIG. 4, a synthesized stress toward the center of the solder is produced. In addition, if the surface shape of spare solder 21 is curved due to the solder resist 22, a stress is applied along this surface. Then, the synthesized stress inversely acts as shown in FIG. 4 to act in a direction in which the solder falls off.

It is possible to prevent (avoid) the spare solder 21 from falling off the wiring substrate 24 due to a surface tension when the spare solder 21 interferes with the solder resist 22, by making the radius r2 of the solder resist opening (the SRO radius) is equal to the height h2 of the spare solder 21 (r2≧h2) or more.

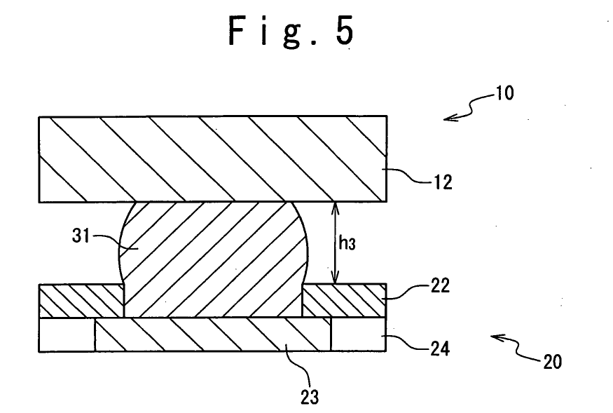

FIG. 5 is a model view showing a configuration example after connection between a semiconductor chip and a package substrate. Referring to FIG. 5, a configuration example after connection between the semiconductor chip 10 and the package substrate 20 of the semiconductor device according to the embodiment of the present invention will be described below.

Upon connection between the semiconductor chip 10 and the package substrate 20, by heat-bonding the solder bump 11 and the spare solder 21 together, a bonded solder 31 is produced. The bonded solder 31 is arranged between the semiconductor chip 10 and the package substrate 20.

The height h1 of the solder bump 11 before connection between the semiconductor chip 10 and the package substrate 20 is made higher than an interval h3 between the semiconductor chip 10 and the package substrate 20 after the connection of them. In other words, “h1≧h3” is given. Further, the interval h3 between the semiconductor chip 10 and the package substrate 20 after the connection of them indicates a height of the bonded solder 31.

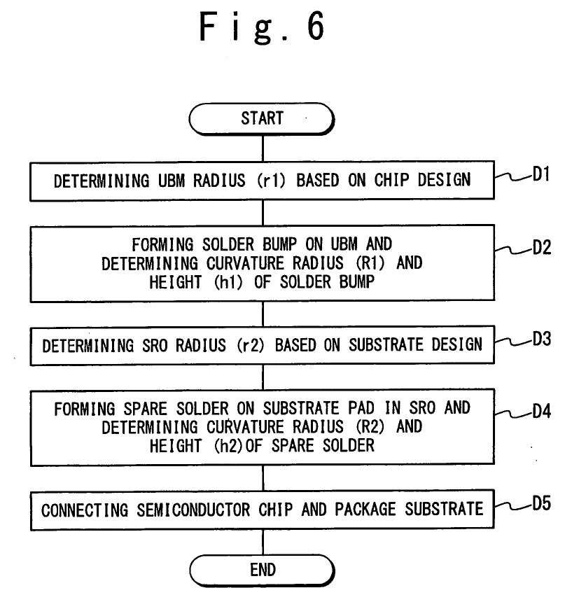

Next, a procedure of determining design values for a solder connection between the semiconductor chip and the package substrate will be described below with reference to FIG. 6. FIG. 6 is a flow chart showing a procedure of determining design values for solder connection.

### (1) Step D1

A semiconductor manufacturing device (chip designing section, not illustrated) carries out chip design. Based on the chip design, an arrangement and a size of the UBM and the UBM radius r1 are determined. In other words, the semiconductor manufacturing device determines the UBM radius r1 based on the chip design. Further, the semiconductor manufacturing device may determine the UBM radius r1 before forming the solder bump 11 on the UBM in practice.

### (2) Step D2

The semiconductor manufacturing device (solder bump section, not illustrated) determines the curvature radius R1 of the solder bump 11 and the height h1 of the solder bump 11 when the solder bump 11 is formed on the UBM 12. In this case, the semiconductor manufacturing device prints solder paste (mixture of solder particles and flux) on the UBM 12 via a mask. Then, the semiconductor manufacturing device carries out reflow heating and flux cleaning.

Generally, the solder amount of the solder bump 11 is not determined based on a structural design of the semiconductor device but determined as an amount capable of stably providing solder based on a size, a pitch, and a layout of the UBM pad or the like in many cases. In other words, the solder amount of the solder bump 11 is defined as a solder amount that is determined under conditions (a mask thickness, an opening radius, and a processing condition or the like) such that a release characteristic of the solder paste of the mask is good, there is no fault in a solder wettability, and short circuit does not occur.

When a solder ball is mounted, after providing the flux on the chip, the solder ball is mounted on the UBM.

Alternatively, according to a plating method, a solder bump is formed on the UBM.

### (3) Step D3

The semi conduct or manufacturing device (substrate designing section, not illustrated) determines the curvature radius R1 of the solder bump carries out substrate design. Based on the substrate design, an arrangement and a size of the SRO and the SRO radius r2 are determined. In other words, the semiconductor manufacturing device determines the SRO radius r2 based on the substrate design.

Generally, the radius that is the same as the UBM radius is employed for the SRO radius in many cases. However, according to the embodiment, some flexibility is given to a ratio between the SRO radius and the UBM radius.

### (4) Step D4

The semiconductor manufacturing device (spare solder section, not illustrated) determines the curvature radius R2 of the spare solder 21 and the height h2 of the spare solder 21 when the spare solder 21 is formed on the substrate pad (the electrode 23) in the SRO. In this case, a manufacturing method of the spare solder 21 is the same as that of the solder bump 11. After the spare solder 21 is formed, the spare solder 21 is pressed to be planarized so that the spare solder 21 is prevented from failing to contact with the solder bump 11 when the spare solder 21 is matched with the solder bump 11.

Generally, in a solder amount of the spare solder 21, a rough indication of the cubic volume is determined in a pseudo manner based on the height of the spare solder 21 and a radius after planarization or the like. In other words, the solder amount of the spare solder 21 is not determined based on a structural design of the semiconductor device, and the solder amount of the spare solder 21 is not changed based on a size, a pitch, and a layout of the substrate pad or the like.

### (5) Step D5

The semiconductor manufacturing device (connection section, not illustrated) carries out a connection between the semiconductor chip 10 and the package substrate 20. In other words, the semiconductor manufacturing device heat-bonds the solder bump 11 to the spare solder 21. In this case, the semiconductor manufacturing device transcribes flux on the solder bump 11 and mounts the solder bump 11 on the corresponding spare solder 21 on the substrate pad. After that, the semiconductor manufacturing device carries out reflow heating and flux cleaning.

In the case of determining the design values between the semiconductor chip and the package substrate according to the above-described procedure, the semiconductor manufacturing device is capable of preventing occurrence of a solder suction phenomenon (suction) upon heat-melting.

Here, the examples regarding a flip chip mounting of the semiconductor chip and the package substrate have been described above. However, the present invention is not limited to these examples. For example, the present invention can be also applied to other semiconductor devices, in which the chip is connected to the substrate by using the Ball Grid Array (BGA) method and a similar method.

Next, the features of the semiconductor device according to the present invention will be described below.

In the semiconductor device according to the present invention, a material of the semiconductor bump is substantially the same as a material of the spare solder. When the semiconductor bump and the spare solder are made of the same materials, the solder suction phenomenon will occur. In order to prevent the electric connection defect due to the suction phenomenon, a ratio between the opening radius (UBM radius) r1, at which the solder bump is brought in contact with the semiconductor chip, and the solder resist opening radius (the SRO radius) r2, at which the spare solder is brought in contact with the package substrate, namely, the ratio r2/r1 is defined to be 0.8 or more and 1.2 or less (in a range from 0.8 to 1.2). In this case, the height h1 of the solder bump is determined to be higher than the height h2 of the spare solder. Here, the height h2 of the spare solder 21 corresponds to the height of the portion that is protruded from the SRO in the spare solder 21 (namely, the height from the surface of the solder resist).

According to the present invention, the solder amount of the solder bump and the solder amount of the spare solder are defined so that the curvature radius R1 of the solder bump and the curvature radius R2 of the spare solder satisfy a relation of “R2≧R1”. In this case, it is defined that the solder amount of the solder bump on the semiconductor chip side is larger than the solder amount of the spare solder on the package substrate side. As a reason of this, other than the fact that a solder ball is used for the solder bump, there is another fact that the solder resist is arranged on the package substrate side and this makes it difficult for the solder amount to increase.

Here, the opening radius r2 of the spare solder (the SRO radius) is defined to be the height h2 of the spare solder or more. As a reason of this, if the opening radius r2 is smaller than the height h2, there is a possibility that a surface tension produced when the spare solder is melted interferes with the solder resist to make the spare solder fall off the package substrate. It is determined that the height h1 of the solder bump before connection between the substrate chip and the package substrate is larger than the interval h3 between the semiconductor chip and the package substrate after the connection. As described above, the present invention relates to a package substrate and a wiring support, which are used for a flip chip type semiconductor device. The semiconductor device according to the present invention includes a connection structure such that solder material having the same composition as that of the solder bump formed on the chip side is used for the spare solder. According to the semiconductor device of the present invention, it is possible to prevent the electric connection defect due to the solder suction phenomenon by finding optimum values with respect to design of the spare solder and the opening of the solder resist based on the relation among the shape of the solder bump, the spare solder and the opening of the solder resist.

In the semiconductor device according to the present invention, there is an opening in an insulating layer at a position opposed to the solder bump of the semiconductor chip on the wiring support. Furthermore, the solder is arranged on an electrode arranged in the opening in the insulating layer. The wiring support is characterized in that a relation between the height h2 of the solder when the solder is melted and the radius r2 of the opening in the insulating layer (the SRO radius) represents r2≧h2. The semiconductor device according to the present invention may include such the wiring support and a following solder connection structure. In this solder connection structure, a composition of the solder that is arranged on the electrode arranged in the opening in the insulating layer is the same as a composition of the solder bump that is formed on the UBM arranged on the semiconductor chip.

In addition, the wiring support included in the semiconductor device according to the present invention includes a component such that the curvature radius R1 when the solder bump is melted in the semiconductor chip provided with the solder bump and the curvature radius R2 when the spare solder is melted in the package substrate are in a relation of R2≧R1, and the height h1 when the solder bump is melted in the semiconductor chip provided with the solder bump and the height h2 when the spare solder is melted in the package substrate are in a relation of h1≧h2. Further, this wiring support is characterized in that a ratio of r1 and r2, namely, a ratio r2/r1 is 0.8 or more and 1.2 or less (in the range from 0.8 to 1.2) where the radius of the opening in the insulating layer (the SRO radius) is r2, and the UBM radius is r1; and the height h3 after connecting the chip to the package substrate and the height h1 of the solder bump before the connection thereof are in a relation of h1>h3.

The embodiments of the present invention are described in detail as above; however, it is apparent that the present invention is not limited to the above embodiment, but may be modified and changed without departing from the scope and spirit of the invention.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A manufacturing method of a semiconductor device comprising:
determining an UBM (Under Bump Metal) radius of an UBM of a chip;
determining a first curvature radius of a solder bump formed on said UBM;
determining a SRO (Solider Resist Opening) radius of a SRO of a substrate such that a ratio of said SRO radius to said UMB radius is in a range from 0.8 to 1.2; and
determining a second curvature radius of a spare solder formed on an electrode in said SRO such that said second curvature radius is equal to or more than said first curvature radius.

2. The manufacturing method of a semiconductor device according to claim 1, further comprising:
determining said SRO radius such that said SRO radius is equal to or larger than a height of said spare solder.

3. The manufacturing method of a semiconductor device according to claim 1, further comprising:
determining a height of said solder bump such that said height of said solder bump is larger than an interval between said chip and said substrate after said solder bump and said spare solder are heat-bonded.

4. The manufacturing method of a semiconductor device according to claim 1, further comprising:
determining a height of said solder bump such that said height of said solder bump is higher than a height of said spare solder.

5. The manufacturing method of a semiconductor device according to claim 1, further comprising:
determining a solder amount of said solder bump such that said solder amount of said solder bump is larger than a solder amount of said spare solder.

6. The manufacturing method of a semiconductor device according to claim 1, wherein a material of said solder bump is substantially the same as a material of said spare solder.

7. A semiconductor device comprising:
a solder resist configured to be provided with a SRO (Solider Resist Opening) of a substrate, a ratio of a SRO radius of said SRO to an UBM (Under Bump Metal) radius of an UBM of a chip mounted on said substrate being in a range from 0.8 to 1.2; and
a spare solder configured to be arranged on an electrode in said SRO, and have a curvature radius is equal to or larger than a curvature radius of a solder bump formed on said UBM.

8. The semiconductor device according to claim 7, wherein said SRO radius is equal to or larger than a height of said spare solder.

9. The semiconductor device according to claim 7, wherein a height of said solder bump is larger than an interval between said chip and said substrate after said solder bump and said spare solder are heat-bonded.

10. The semiconductor device according to claim 7, wherein a height of said solder bump is higher than a height of said spare solder.

11. The semiconductor device according to claim 7, wherein a solder amount of said solder bump is larger than a solder amount of said spare solder.

12. The semiconductor device according to claim 7, wherein a material of said solder bump is substantially the same as a material of said spare solder.
